(19) United States
(12) Patent Application Publication
(10) Pub. No.: US 2008/0013580 A1
(43) Pub. Date: Jan. 17, 2008

(54) SURFACE-EMITTING TYPE SEMICONDUCTOR LASER AND ITS MANUFACTURING METHOD

(75) Inventor: Satoshi KAKINUMA, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/776,205

(22) Filed: Jul. 11, 2007

(30) Foreign Application Priority Data
Jul. 13, 2006 (JP) 2006-193075
Apr. 16, 2007 (JP) 2007-107336

(51) Int. Cl. H01S 5/00; H01L 21/02

(52) U.S. Cl. 372/43.01; 438/22

(57) ABSTRACT

A surface-emitting type semiconductor laser has: a light emitting section having a first mirror, an active layer formed above the first mirror and a second mirror formed above the active layer; a support section having layers that are common with the first mirror, the active layer and the second mirror; and a diode section having a semiconductor layer formed above the support section, wherein an optical film thickness of the semiconductor layer is not an odd multiple or an even multiple of λ/4, where λ is a design wavelength of light that is emitted by the light emitting section.

### BACKGROUND

1. Technical Field

Several aspects of the present invention relate to surface-emitting type semiconductor lasers and methods for manufacturing the same.

2. Related Art

A surface-emitting type semiconductor laser may be damaged by static electricity caused by machines or operators during the manufacturing process as its electrostatic breakdown voltage of the device itself is low. A variety of measures are usually implemented in the manufacturing process to remove static electricity, but these measures have limitations.

For example, Japanese Laid-open Patent Application JP-A-2004-6548 describes a technique in which dielectric films and metal films are laminated to compose a capacitor element, and the capacitor element is used as a breakdown protection device. In this case, the dielectric films and metal films need to be laminated, and therefore it may take a long time in laminating layers in order to form a desired capacitor element.

### SUMMARY

In accordance with an advantage of some aspects of the invention, there are provided a surface-emitting type semiconductor laser by which its manufacturing cost and time can be reduced, and a method for manufacturing the same.

In accordance with an embodiment of the invention, a surface-emitting type semiconductor laser includes:

a light emitting section having a first mirror, an active layer formed above the first mirror and a second mirror formed above the active layer;

a support section having layers that are common with the first mirror, the active layer and the second mirror; and

a diode section having a semiconductor layer formed above the support section,

wherein an optical film thickness of the semiconductor layer is not an odd multiple or an even multiple of λ/4, where λ is a design wavelength of light that is emitted by the light emitting section.

According to the surface-emitting type semiconductor laser, as described below, by obtaining a reflection spectrum of a semiconductor multilayer film obtained through forming layers on a substrate, whether or not each of the layers is formed in a desired film thickness can be judged. Accordingly, based on whether or not the semiconductor multilayer film is formed in a desired film thickness, a determination can be made as to whether or not the light emitting section and the diode section are manufactured according to the design. In this manner, it is possible to determine in an initial stage of the manufacturing process as to whether or not the light emitting section and the diode section are manufactured according to the design, such that an electrostatic discharge (ESD) withstanding test after mounting can be omitted. As a result, according to the invention, the manufacturing cost and time can be reduced.

It is noted that, in descriptions concerning the invention, the term “above” may be used, for example, in a manner as “a specific member (hereafter referred to as ‘B’) formed ‘above’ another specific member (hereafter referred to as ‘A’).” In descriptions concerning the invention, the term “above” is used, in such an exemplary case described above, assuming that the use of the term includes a case in which “B” is formed directly on “A,” and a case in which “B” is formed over “A” through another member on “A.”

Also, in the invention, the “design wavelength” is a wavelength of light that has the maximum intensity among light emitted from the light emitting section.

Also, in the invention, the “optical film thickness” is a value obtained by multiplying an actual film thickness of a layer and a refractive index of material composing the layer.

In accordance with another embodiment of the invention, a surface-emitting type semiconductor laser includes:

a light emitting section having a first mirror, an active layer formed above the first mirror and a second mirror formed above the active layer;

a support section having layers that are common with the first mirror, the active layer and the second mirror; and

a diode section having a semiconductor layer formed above the support section,

wherein the position of a dip caused by photoabsorption of the semiconductor layer in a reflection spectrum is inside a stop band of the first mirror and the second mirror, and a minimum section of the dip by photoabsorption of the semiconductor layer is deviated from a dip caused by photoabsorption of the active layer.

In the surface-emitting type semiconductor laser in accordance with the present embodiment, the diode section may be composed of the semiconductor layer, and the semiconductor layer may be formed directly on a layer common with the second mirror of the support section.

In accordance with still another embodiment of the invention, a surface-emitting type semiconductor laser includes:

a light emitting section having a first mirror, an active layer formed above the first mirror and a second mirror formed above the active layer; and

a diode section having a semiconductor layer formed above the light emitting section,

wherein an optical film thickness of the semiconductor layer is not an odd multiple or an even multiple of λ/4, where λ is a design wavelength of light that is emitted by the light emitting section.

In accordance with yet another embodiment of the invention, a surface-emitting type semiconductor laser includes:

a light emitting section having a first mirror, an active layer formed above the first mirror and a second mirror formed above the active layer; and

a diode section having a semiconductor layer formed above the light emitting section,

wherein the position of a dip caused by photoabsorption of the semiconductor layer in a reflection spectrum is inside a stop band of the first mirror and the second mirror, and a minimum section of the dip by photoabsorption of the semiconductor layer is deviated from a dip caused by photoabsorption of the active layer.

In the surface-emitting type semiconductor laser in accordance with the present embodiment, the diode section may be composed of the semiconductor layer, and the semiconductor layer may be formed directly on the second mirror.

In the surface-emitting type semiconductor laser in accordance with the present embodiment, the light emitting section and the diode section may be electrically connected in parallel with each other, and the diode section has a rectification action in a reverse direction with respect to the light emitting section.

In the surface-emitting type semiconductor laser in accordance with the present embodiment, the diode section may be a photodetector section, and the semiconductor layer may have a photoabsorption layer.

It is noted that, in the present invention, the “photoabsorption layer” conceptually includes a depletion layer.

In the surface-emitting type semiconductor laser in accordance with the present embodiment, the semiconductor layer may include a first semiconductor layer of a first conductivity type, and a second semiconductor layer of a second conductivity type formed above the first semiconductor layer.

In the surface-emitting type semiconductor laser in accordance with the present embodiment, the semiconductor layer has an optical film thickness that may be greater than λ/4 but smaller than λ/2.

In the surface-emitting type semiconductor laser in accordance with the present embodiment, each of the first mirror and the second mirror may be composed of a distributed Bragg reflection type mirror, and an optical film thickness of each layer in the distributed Bragg reflection type mirror may be an odd multiple of λ/4.

In accordance with still another embodiment of the invention, a method for manufacturing a surface-emitting type semiconductor laser includes the steps of:

forming a semiconductor multilayer film, including the steps of forming a first mirror above a substrate, forming an active layer above the first mirror, forming a second mirror above the active layer, and forming a semiconductor layer above the second mirror;

conducting a reflection coefficient examination on the semiconductor multilayer film, after the step of forming a semiconductor multilayer film; and

patterning the semiconductor multilayer film to form a light emitting section having the first mirror, the active layer and the second mirror, and a diode section having the semiconductor layer, after the step of conducting a reflection coefficient examination,

wherein the semiconductor layer is formed to have an optical film thickness that is not an odd multiple or an even multiple of λ/4, where λ is a design wavelength of light that is emitted by the light emitting section.

In accordance with yet another embodiment of the invention, a second method for manufacturing a surface-emitting type semiconductor laser includes the steps of:

forming a semiconductor multilayer film, including the steps of forming a first mirror above a substrate, forming an active layer above the first mirror, forming a second mirror above the active layer, and forming a semiconductor layer above the second mirror;

conducting a reflection coefficient examination on the semiconductor multilayer film, after the step of forming a semiconductor multilayer film; and

patterning the semiconductor multilayer film to form a light emitting section having the first mirror, the active layer and the second mirror, and a diode section having the semiconductor layer, after the step of conducting a reflection coefficient examination,

wherein the position of a dip caused by photoabsorption of the semiconductor layer in a reflection spectrum obtained by the reflection coefficient examination is inside a stop band of the first mirror and the second mirror, and a minimum section of the dip caused by photoabsorption of the semiconductor layer is deviated from a dip caused by photoabsorption of the active layer.

### BRIEF DESCRIPTION OF THE DRAWINGS

FIG. 1 is a schematic cross-sectional view of a surface-emitting type semiconductor laser in accordance with an embodiment of the invention.

FIG. 2 is a schematic plan view of the surface-emitting type semiconductor laser in accordance with the embodiment of the invention.

FIG. 3 is a cross-sectional view schematically showing a step in a method for manufacturing a surface-emitting type semiconductor laser in accordance with an embodiment of the invention.

FIG. 4 is a graph showing a reflection spectrum of a semiconductor multilayer film in accordance with an embodiment of the invention.

FIG. 5 is a graph showing a reflection spectrum of a semiconductor multilayer film in accordance with a comparison example.

FIG. 6 is a graph schematically showing a reflection spectrum of a semiconductor multilayer film in accordance with a comparison example.

FIG. 7 is a cross-sectional view schematically showing a step in the method for manufacturing a surface-emitting type semiconductor laser in accordance with the embodiment of the invention.

FIG. 8 is a schematic cross-sectional view of a surface-emitting type semiconductor laser in accordance with a modified example of the embodiment of the invention.

FIG. 9 is a graph showing a reflection spectrum of a semiconductor multilayer film in accordance with a third modified example.

FIG. 10 is a graph showing a reflection spectrum of a semiconductor multilayer film in accordance with the third modified example.

### DESCRIPTION OF EXEMPLARY EMBODIMENTS

Preferred embodiments of the invention are described below with reference to the accompanying drawings.

1. First, a surface-emitting type semiconductor laser 100 in accordance with an embodiment of the invention is described.

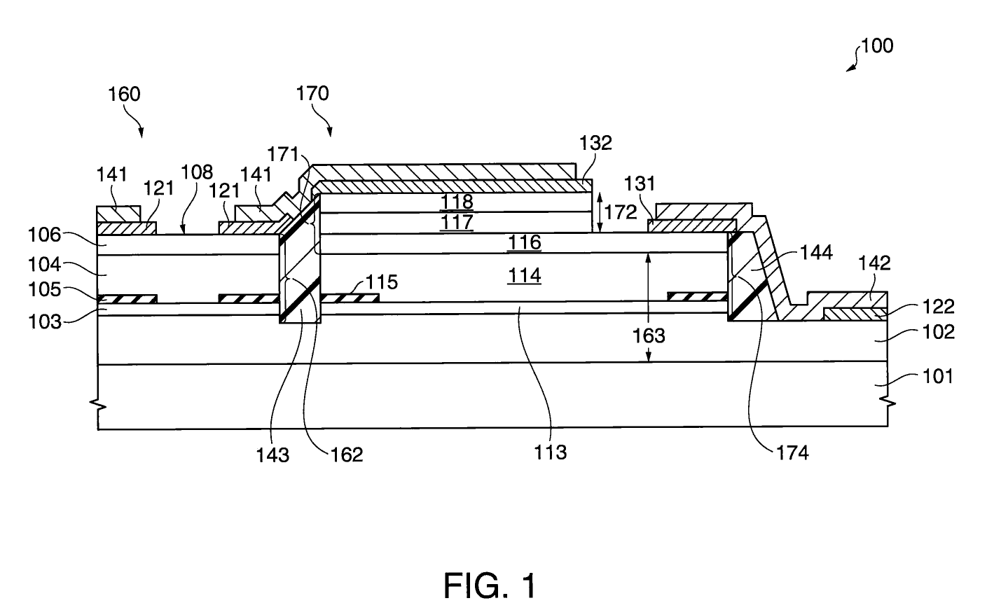

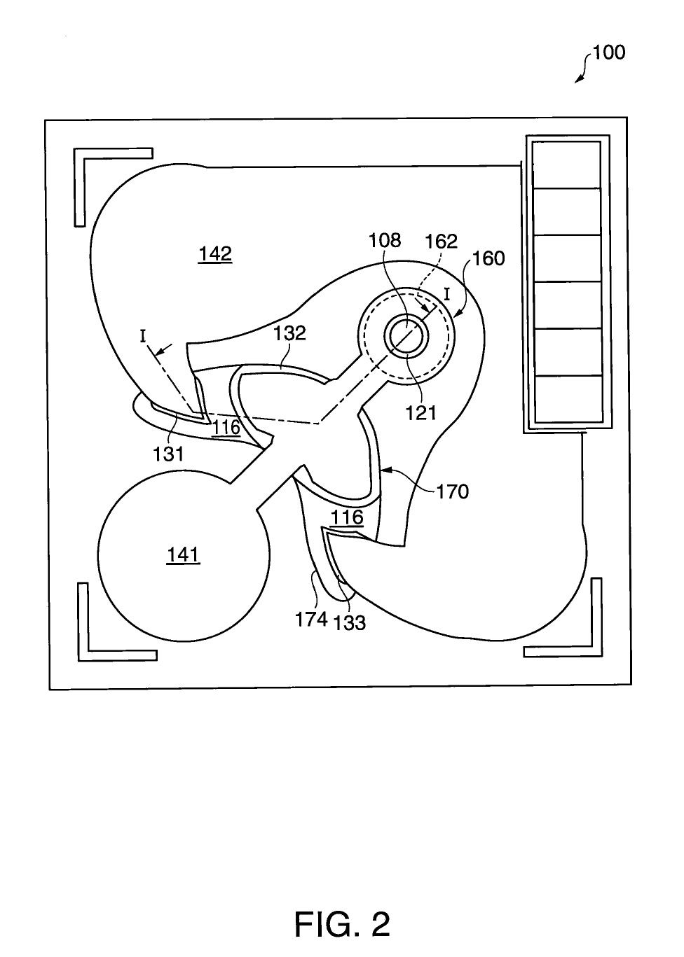

FIG. 1 is a schematic cross-sectional view of the surface-emitting type semiconductor laser 100, and FIG. 2 is a schematic plan view of the surface-emitting type semiconductor laser 100. It is noted that FIG. 1 is a cross-sectional view taken along a line I-I of FIG. 2.

The surface-emitting type semiconductor laser 100 in accordance with the present embodiment may include, as shown in FIG. 1 and FIG. 2, a substrate 101, a light emitting section 160, a support section 163, a diode section 170, a first connection electrode 141, and a second connection electrode 142. The light emitting section 160 and the diode section 170 are formed above a common substrate (the substrate 101). In other words, the light emitting section 160 and the diode section 170 are monolithically formed.

As the substrate 101, for example, an n-type GaAs substrate may be used.

The light emitting section 160 includes a first mirror 102 formed on the substrate 101, an active layer 103 formed on the first mirror 102, a second mirror 104 formed on the active layer 103, and a contact layer 106 formed on the second mirror 104. The first mirror 102 is, for example, a distributed Bragg reflection type (DBR) mirror of 40.5 pairs of alternately laminated n-type Al_{0.9}Ga_{0.1}As layers and n-type Al_{0.12}Ga_{0.88}As layers. The active layer 103 has a multiple quantum well (MQW) structure in which quantum well structures each formed from, for example, a GaAs well layer and an Al_{0.3}Ga_{0.7}As barrier layer are laminated in three layers. The second mirror 104 is, for example, a DBR mirror of 22-23 pairs of alternately laminated p-type Al_{0.9}Ga_{0.1}As layers and p-type Al_{0.12}Ga_{0.88}As layers. The contact layer 106 is, for example, a p-type GaAs layer. The first mirror 102, the active layer 103 and the second mirror 104 may compose a vertical resonator. It is noted that the composition of each of the layers and the number of the layers are not particularly limited to the above. The p-type second mirror 104, the active layer 103 that is not doped with an impurity and the n-type first mirror 102 form a pin diode.

Each layer in the DBR mirrors composing the first mirror 102 and the second mirror 104 has an optical film thickness of, for example, an odd multiple of λ/4. It is noted that λ is a design wavelength of light that is emitted by the light emitting section 160.

A portion of the first mirror 102, the active layer 103, the second mirror 104 and the contact layer 106 may form, for example, a columnar semiconductor laminate (columnar section) 162. The columnar section 162 has a plane configuration that is, for example, in a circular shape.

Also, as shown in FIG. 1, for example, at least one of the layers composing the second mirror 104 can be formed as a current constricting layer 105. The current constricting layer 105 is formed in a region near the active layer 103. As the current constricting layer 105, for example, an oxidized AlGaAs layer can be used. The current constricting layer 105 is a dielectric layer having an opening section, and is formed in a ring shape.

The light emitting section 160 may further include a first electrode 122 that is electrically connected to the first mirror 102, and a second electrode 121 that is electrically connected to the second mirror 104 through the contact layer 106. The first electrode 122 and the second electrode 121 may be used to drive the light emitting section 160. The first electrode 122 is provided, for example, on the top surface of the first mirror 102, and below the second connection electrode 142. The first electrode 122 is provided in a manner to surround the columnar section 162 and the support section 163 as viewed in a plan view. The second electrode 121 is provided, for example, on the top surface of the contact layer 106. The second electrode 121 has a plane configuration that is, for example, a ring shape, and has an opening section on the columnar section 162. The opening section has a plane configuration that is, for example, a circular shape. The opening section forms a region (laser beam emission surface) 108 where the second electrode 121 is not provided on the top surface of the contact layer 106.

The diode section 170 may be composed of a diode having a rectification action, such as, for example, a pn junction diode or a Schottky barrier diode. The diode section 170 may be electrically connected in parallel with the light emitting section 160. The diode section 170 may have a rectification action in a reverse direction with respect to the light emitting section 160. In the surface-emitting type semiconductor laser 100 shown in FIG. 1 and FIG. 2, even when a reverse bias voltage is applied to the light emitting section 160, a current flows through the diode section 170, such that the electrostatic destruction withstanding voltage against a reverse bias voltage is remarkably improved.

The diode section 170 may include a semiconductor layer 171 formed on the support section 163, a third electrode 131, a fourth electrode 133 and a fifth electrode 132. The semiconductor layer 171 may include, for example, a first semiconductor layer 116 and a second semiconductor layer 118 formed above the first semiconductor layer 116. The first semiconductor layer 116 is composed of a layer common with the contact layer 106 of the light emitting section 160. The first semiconductor layer 116 is, for example, a GaAs layer of a first conductivity type (for example, p-type). The second semiconductor layer 118 is, for example, a GaAs layer of a second conductivity type (for example, n-type). The semiconductor layer 171 may further include a third semiconductor layer 117 formed between the first semiconductor layer 116 and the second semiconductor layer 118. As the third semiconductor layer 117, for example, GaAs that is not doped with an impurity (GaAs in intrinsic semiconductor) may be used. An energy gap of the constituent material of at least one layer of the first semiconductor layer 116, the second semiconductor layer 118 and the third semiconductor layer 117 is narrower than, for example, an energy gap of the constituent material of the first mirror 102 and the second mirror 104 of the light emitting section 160.

The optical film thickness of the semiconductor layer 171 (more specifically, the first semiconductor layer 116, the second semiconductor layer 118 and the third semiconductor layer 117 as a whole) is not an odd multiple of λ/4 or an even multiple of λ/4. It is noted that λ is a design wavelength of light that is emitted by the light emitting section 160. The optical film thickness of the semiconductor layer 171 may be set to a range, for example, between λ/4 and λ/2.

For example, when the first semiconductor layer 116 is a p-type GaAs layer, the second semiconductor layer 118 is an n-type GaAs layer, and the third semiconductor layer 117 is composed of GaAs in intrinsic semiconductor, each of the layers has generally the same refractive index. In this case, when the design wavelength λ is, for example, 850 nm, the refractive index of each of the layers is about 3.6, and the actual film thickness of the semiconductor layer 171 can be set in a range between 59 nm and 118 nm.

Also, the optical film thickness of the semiconductor layer 171 may be set in a range of, for example, (2m+1)λ/8±λ/16 (where m is a natural number). Also, the optical film thickness of the semiconductor layer 171 may be set in a range of, for example, (2m+1)λ/8. Also, the optical film thickness of the semiconductor layer 171 may be set at, for example, an intermediate value of a range between λ/4 and λ/2 (more specifically, 3λ/8). Consequently, the design margin for the semiconductor layer 171 can be broadened. As a result, in a reflection coefficient examination to be described below, a judgment can be more securely made as to whether each of the layers in the semiconductor multilayer film 150 is formed in a desired film thickness.

Further, in accordance with the present embodiment, one layer among the layers composing the semiconductor layer 171 (for example, the third semiconductor layer 117) may be set to an optical film thickness that is not an odd multiple of λ/4 or an even multiple of λ/4. At the same time, the other layers among the layers composing the semiconductor layer 171 (for example, the first semiconductor layer 116 and the second semiconductor layer 118) each may be set to an optical film thickness that is an odd multiple of λ/4 or an even multiple of λ/4.

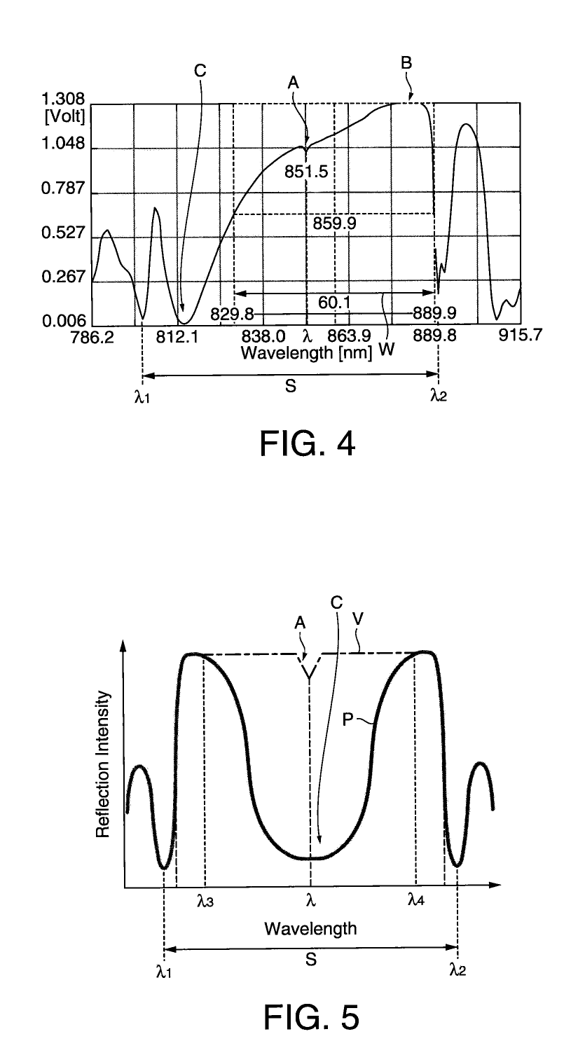

Also, the position of a dip C caused by photoabsorption of the semiconductor layer 171 (more specifically, the first semiconductor layer 116, the second semiconductor layer 118 and the third semiconductor layer 117) in a reflection spectrum (see FIG. 4) is inside a stop band S of the first mirror 102 and the second mirror 104. Furthermore, a minimum section of the dip C caused by photoabsorption of the semiconductor layer 171 is deviated from a dip A caused by photoabsorption of the active layer 103. Details thereof shall be described below.

The first semiconductor layer 116 may have a plane configuration composed of an oval shape having a center section that is bent and protrudes toward the columnar section 162. The third electrode 131 and the fourth electrode 133 are formed on the first semiconductor layer 116. The third electrode 131 is provided, for example, at one end section of the bent oval shape of the plane configuration of the first semiconductor layer 116, as viewed in a plan view. The fourth electrode 133 is provided, for example, at the other end section of the bent oval shape. The third electrode 131 and the fourth electrode 133 are formed at positions mutually separated from each other. At least one portion among the shortest virtual line connecting the third electrode 131 and the fourth electrode 133 may not overlap the first semiconductor layer 116, as viewed in a plan view.

The second semiconductor layer 118 and the third semiconductor layer 117 may compose a columnar semiconductor laminate (first columnar section). The columnar section is formed on a portion of the top surface of the first semiconductor layer 116, for example, as shown in FIG. 1. The third electrode 131 and the fourth electrode 133 are formed in a region in the top surface of the first semiconductor layer 116 where the columnar section is not formed.

The fifth electrode 132 is formed on the second semiconductor layer 118. The fifth electrode 132 may have a plane configuration that is in a generally oval shape, for example, as shown in FIG. 2.

The support section 163 may include the first mirror 102 formed on the substrate 101, a fourth semiconductor layer 113 formed on the first mirror 102 and a fifth semiconductor layer 114 formed on the fourth semiconductor layer 113. The fourth semiconductor layer 113 is composed of a layer common with the active layer 103 of the light emitting section 160. In other words, the fourth semiconductor layer 113 has the same layered structure as that of the active layer 103.

The fifth semiconductor layer 114 is composed of a layer common with the second mirror 104 of the light emitting section 160. In other words, the fifth semiconductor layer 114 has the same layered structure as that of the second mirror 104. Each of the layers in the DBR mirror composing the fifth semiconductor layer 114 may have an optical film thickness that is, for example, an odd multiple of λ/4. The semiconductor layer 171 of the diode section 170 is formed directly on the fifth semiconductor layer 114, for example, as shown in FIG. 1. The fifth semiconductor layer 114 may be a part of the support section 163, and a part of the diode section 170. In other words, the fifth semiconductor layer 114 can function as a part of the diode section 170. Also, the fifth semiconductor layer 114 may have an oxidized layer 115. The oxidized layer 115 is formed concurrently when forming the current constricting layer 105 of the light emitting section 160.

For example, a part of the first mirror 102, the fourth semiconductor layer 113, the fifth semiconductor layer 114 and the first semiconductor layer 116 may form a columnar semiconductor laminate (second columnar section) 174.

The first connection electrode 141 and the second connection electrode 142 can connect the light emitting section 160 in parallel with the diode section 170. The first connection electrode 141 can electrically connect the second electrode 121 of the light emitting section 160 with the fifth electrode 132 of the diode section 170. The second connection electrode 142 can electrically connect the first electrode 122 of the light emitting section 160 with the third electrode 131 and the fourth electrode 133 of the diode section 170.

A dielectric layer 143 is formed between the columnar section 162 of the light emitting section 160 and the first columnar section 172 and the second columnar section 174 of the diode section 170. The dielectric layer 143 has a downwardly sloped upper surface extending from the side of the fifth electrode 132 to the side of the second electrode 121, for example, as shown in FIG. 1. Also, a dielectric layer 144 is formed between the first electrode 122 of the light emitting section 160 and the second columnar section 174 of the diode section 170. The side surface of the dielectric layer 144 is sloped such that the surface of the dielectric layer 144 is gently sloped, for example, as shown in FIG. 1.

2. Next, one example of a method for manufacturing the surface-emitting type semiconductor laser 100 in accordance with an embodiment of the invention is described with reference to the accompanying drawings.

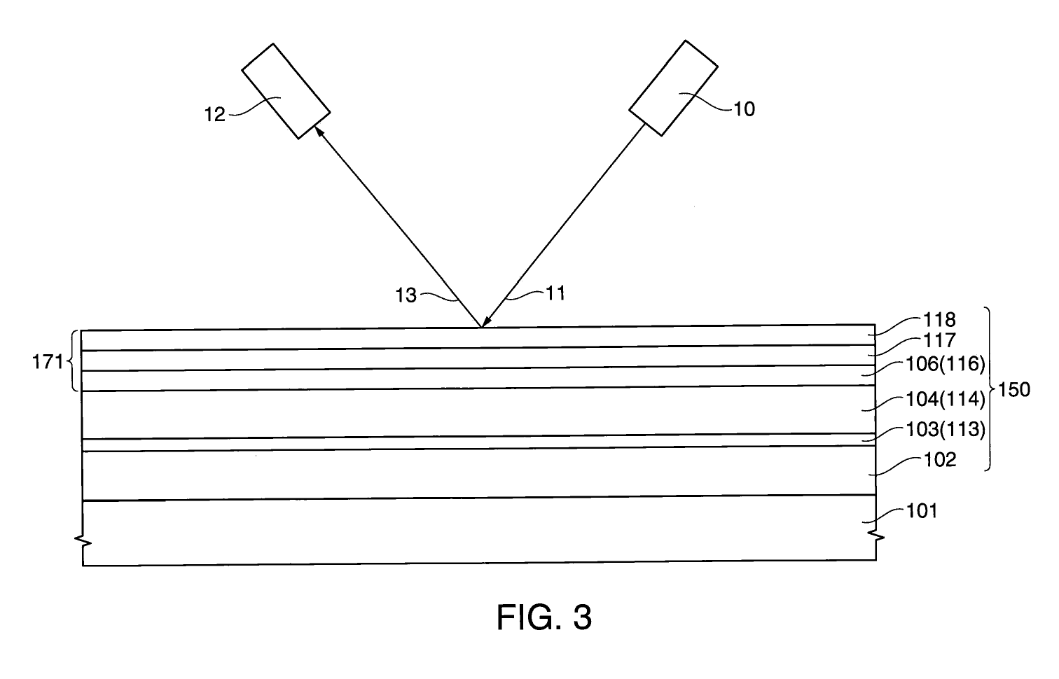

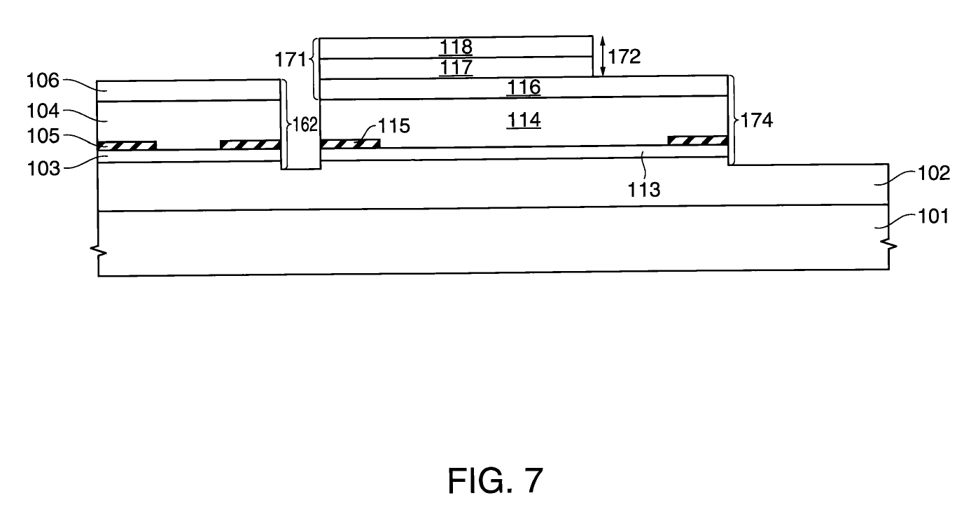

FIG. 3 and FIG. 7 are cross-sectional views showing the steps of a method for manufacturing the surface-emitting type semiconductor laser 100 shown in FIG. 1 and FIG. 2, and correspond to the cross-sectional view shown in FIG. 1, respectively.

(1) First, as a substrate 101, for example, an n-type GaAs substrate is prepared, as shown in FIG. 3. Next, on the substrate 101, a semiconductor multilayer film 150 is formed by epitaxial growth while modifying its composition. The semiconductor multilayer film 150 is formed from successively laminated semiconductor layers composing a first mirror 102, an active layer 103, a second mirror 104, a contact layer 106, a third semiconductor layer 117 and a second semiconductor layer 118, respectively. The semiconductor layer composing the active layer 103 is also the semiconductor layer composing the fourth semiconductor layer 113. The semiconductor layer composing the second mirror 104 is also the semiconductor layer composing the fifth semiconductor layer 114. The semiconductor layer composing the contact layer 106 is also the semiconductor layer composing the first semiconductor layer 116. When growing the second mirror 104, at least one layer thereof near the active layer 103 is formed to be a layer that is later oxidized and becomes a current constricting layer 105 and an oxidized layer 115. As the layer to be oxidized, for example, an AlGaAs layer with its Al composition being 0.95 or higher may be used.

(2) Next, a reflection coefficient examination is conducted on the semiconductor multilayer film 150. In the present step, by obtaining a reflection spectrum for a wavelength, a judgment can be made as to whether each of the layers of the semiconductor multilayer film 150 is formed to a desired film thickness. The reflection coefficient examination may be conducted, for example, as shown in FIG. 3, through irradiating light 11 from a light source 10 that emits white light through a diffraction grating (not shown) on a surface of the semiconductor multilayer film 150, and making reflected light 13 incident upon a photodetector device 12 such as a CCD through a mirror (not shown).

As described above, the total optical film thickness of the first semiconductor layer 116, the second semiconductor layer 118 and the third semiconductor layer 117 is not an odd multiple of λ/4 or an even multiple of λ/4. For this reason, when a reflection coefficient examination is conducted on the semiconductor multilayer film 150 in accordance with the present embodiment, a reflection spectrum shown, for example, in FIG. 4 can be obtained. For example, in the reflection spectrum shown in FIG. 4, a dip A is observed. The wavelength at the minimum section of the dip A is 851.5 nm. This wavelength corresponds to the design wavelength λ of light emitted from the light emitting section 160.

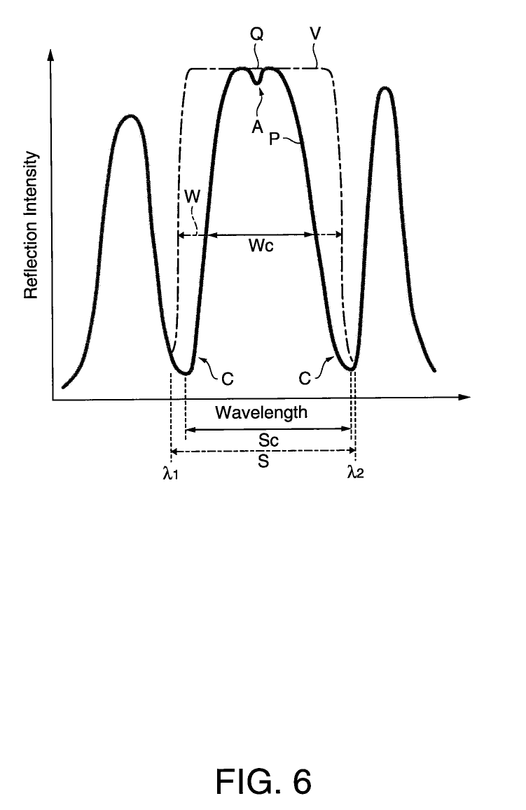

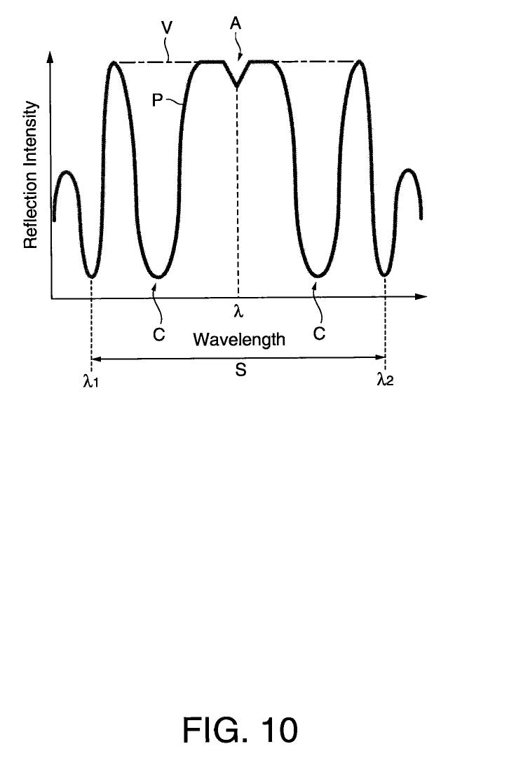

In contrast, when the total optical film thickness of the first semiconductor layer 116, the second semiconductor layer 118 and the third semiconductor layer 117 is, for example, an odd multiple of λ/4, a reflection spectrum P, for example, shown in FIG. 5 is obtained. In the reflection spectrum P, photoabsorption that obscures the dip A described above corresponding to the design wavelength λ (850 nm and its neighborhood) occurs (indicated by an arrow C in the figure). It is noted that FIG. 5, and FIG. 6 and FIG. 10 to be described below show a reflection spectrum V of a multilayer film composed of a first mirror 102, an active layer 103 and a second mirror 104 formed on the substrate 101 (in other words, a multilayer film that does not have a semiconductor layer 171) by a dot-and-dash line.

Also, in the reflection spectrum in accordance with the present embodiment, as shown in FIG. 4, the full width at half maximum W of the peak B having the maximum intensity is, for example, 60.1 nm. In the present embodiment, a region indicated by the full width at half maximum W can be defined as a reflection band of the DBR mirrors composing the first mirror 102 and the second mirror 104.

In contrast, when the total optical film thickness of the first semiconductor layer 116, the second semiconductor layer 118 and the third semiconductor layer 117 is, for example, an even multiple of λ/4, a reflection spectrum shown, for example, in FIG. 6 can be obtained. In the reflection spectrum shown in FIG. 6, photoabsorption that obscures both ends of the reflection band of the DBR mirrors occurs (indicated by an arrow C in the figure), the full width at half maximum Wc and stop band Sc on actual measurement become narrower than the original width (full width at half maximum W) of the reflection band and stop band S of the DBR mirrors. It is noted that the original stop band S of the DBR mirrors is a wavelength band between a wavelength λ₁ and a wavelength λ₂. The wavelength λ₁ is a wavelength at a point, in the reflection spectrum V of a multilayer film that does not have a semiconductor layer 171, where the reflection intensity initially becomes a minimum value as viewed from the region having the maximum reflection intensity toward the shorter wavelength side (excluding the minimum section of the dip A caused by photoabsorption). Also, the wavelength λ₂ is a wavelength at a point, in the reflection spectrum V of a multilayer film that does not have a semiconductor layer 171, where the reflection intensity initially becomes a minimum value as viewed from the region having the maximum reflection intensity toward the longer wavelength side (excluding the minimum section of the dip A caused by photoabsorption).

In the reflection spectrum in accordance with the present embodiment, as shown in FIG. 4, the position of the dip C caused by photoabsorption of the semiconductor layer 171 (in other words, the first semiconductor layer 116, the second semiconductor layer 118 and the third semiconductor layer 117) is inside the stop band of the first mirror 102 and the second mirror 104 (the original stop band of the DBR mirrors) S. In other words, among the end points of the dip C caused by photoabsorption of the semiconductor layer 171, a wavelength λ₃ at the end point on the lower wavelength side (see FIG. 5) is greater than the wavelength λ₁ described above, and a wavelength λ₄ at the end point on the longer wavelength side is smaller than the wavelength λ₂ described above. It is noted that the end points of the dip C caused by photoabsorption of the semiconductor layer 171 are points at which the end sections of the dip C overlap the reflection spectrum V of a multilayer film that does not have a semiconductor layer 171.

Furthermore, in the reflection spectrum in accordance with the present embodiment, as shown in FIG. 4, the minimum section of the dip C caused by photoabsorption of the semiconductor layer 171 is deviated from the dip A caused by photoabsorption of the active layer 103. In other words, all of the wavelengths in the minimum section of the dip C caused by photoabsorption of the semiconductor layer 171 are different from all of the wavelengths in the dip A caused by photoabsorption of the active layer 103. It is noted that the minimum section of the dip C caused by photoabsorption of the semiconductor layer 171 is a point or a band (having a width) at which the reflection intensity assumes a minimum value due to photoabsorption of the semiconductor layer 171. Also, the dip A caused by photoabsorption of the active layer 103 refers to a portion dipped from a virtual reflection spectrum Q (see FIG. 6) of the semiconductor multilayer film 150, which is given when it is assumed that photoabsorption by the active layer 103 does not occur.

The position and width of the dip C caused by photoabsorption of the semiconductor layer 171 can be adjusted by changing, for example, the composition and material of the semiconductor layer 171. Also, position and width of the dip A caused by photoabsorption of the active layer 103 can be adjusted by changing, for example, the composition and material of the active layer 103. Further, the position and width of the stop band S of the first mirror 102 and the second mirror 104 can be adjusted by changing, for example, the composition and material of at least one of the first mirror 102 and the second mirror 104.

From the above, in the reflection spectrum in accordance with the present embodiment, as shown in FIG. 4, the dip A corresponding to the design wavelength λ of light that is emitted from the light emitting section 160, and the original reflection band width (full width at half maximum W) and stop band S of the DBR mirrors composing the first mirror 102 and the second mirror 104 can be observed. By this, whether or not each of the layers (the first mirror 102, the active layer 103 and the second mirror 104) composing the light emitting section 160 is formed to a desired film thickness can be judged. When each of the layers composing the light emitting section 160 is formed to a desired film thickness, it can be judged that each of the layers (the first semiconductor layer 116, the third semiconductor layer 117 and the second semiconductor layer 118) composing the diode section 170 formed above the aforementioned layers is formed to a desired film thickness, because these layers are formed by the same apparatus.

(3) Then, the semiconductor multilayer film 150 is patterned, thereby forming a second semiconductor layer 118 and a third semiconductor layer 117 each in a desired configuration, as shown in FIG. 7. By this, a first columnar section 172 of the diode section 170 is formed. Also, the semiconductor multilayer film 150 is patterned, thereby forming a contact layer 106, a first semiconductor layer 116, a second mirror 104, a fifth semiconductor layer 114, an active layer 103, a fourth semiconductor layer 113 and a first mirror 102, each in a desired configuration. By this, a columnar section 162 of the light emitting section 160 and a second columnar section 174 of the diode section 170 are formed. The semiconductor multilayer film 150 may be patterned by using, for example, lithography technique and etching technique.

Next, by placing the substrate 101 on which the columnar sections 162, 172 and 174 are formed through the aforementioned steps in a water vapor atmosphere at about 400° C., for example, the layer to be oxidized is oxidized from its side surface, whereby a current constricting layer 105 of the light emitting section 160 and an oxidized layer 115 of the diode section 170 are formed.

(4) Next, as shown in FIG. 1, dielectric layers 143 and 144 are formed on the first mirror 102 and on the sides of the columnar sections 162, 172 and 174. First, a dielectric layer composed of polyimide resin or the like is formed over the entire surface by using, for example, a spin coat method. Then, the top surface of the first columnar section 172 is exposed by using, for example, a CMP method. Then, the dielectric layer is patterned by using, for example, lithography technique and etching technique. In this manner, the dielectric layers 143 and 144 are formed in desired configurations, respectively.

Then, first through fifth electrodes 122, 121, 131, 133 and 132 are formed. The electrodes may be formed in desired configurations, respectively, by, for example, a combination of a vacuum vapor deposition method and a lift-off method. The order of forming the electrodes is not particularly limited. The first electrode 122 and the fifth electrode 132 each may be formed from a laminated film of, for example, layers of an alloy of gold and germanium (AuGe), nickel (Ni) and gold (Au). The second electrode 121, the third electrode 131 and the fourth electrode 133 each may be formed from, for example, a laminated film of layers of platinum (Pt) and gold (Au).

Next, a first connection electrode 141 and a second connection electrode 142 are formed. The electrodes may be formed in desired configurations, respectively, by, for example, a combination of a vacuum vapor deposition method and a lift-off method. The order of forming the electrodes is not particularly limited. The first connection electrode 141 and the second connection electrode 142 may be composed of, for example, gold (Au).

(5) By the steps described above, the surface-emitting type semiconductor laser 100 in accordance with the present embodiment can be obtained, as shown in FIG. 1 and FIG. 2.

(6) It is noted that, if necessary, a reflection coefficient examination may be conducted on the surface-emitting type semiconductor laser 100 thus obtained, to thereby obtain a reflection spectrum. This examination step may be conducted after the electrodes on the surface-emitting type semiconductor laser 100 have been removed by etching or the like.

3. In accordance with the present embodiment, as described above, by obtaining a reflection spectrum of the semiconductor multilayer film 150 obtained by forming layers on the substrate 101, a judgment can be made as to whether or not each of the layers is formed to a desired film thickness. Accordingly, based on whether the semiconductor multilayer film 150 is formed to a desired film thickness, a judgment can be made as to whether or not the light emitting section 160 and the diode section 170 are manufactured according to their design. In this manner, because a judgment can be made in an initial stage of the manufacturing process as to whether the light emitting section 160 and the diode section 170 are formed according to their design, tests such as an electrostatic discharge (ESD) withstanding test after mounting can be omitted. As a result, according to the present embodiment, the manufacturing cost and time can be reduced.

4. Next, modified examples of the present embodiment are described. It is noted that features different from those of the embodiment example described above (hereafter referred to as the “example of surface-emitting type semiconductor laser 100”) shall be described, and description of the other features shall be omitted. Also, members having similar functions as those of the example of surface-emitting type semiconductor laser 100 are appended with the same reference numbers.

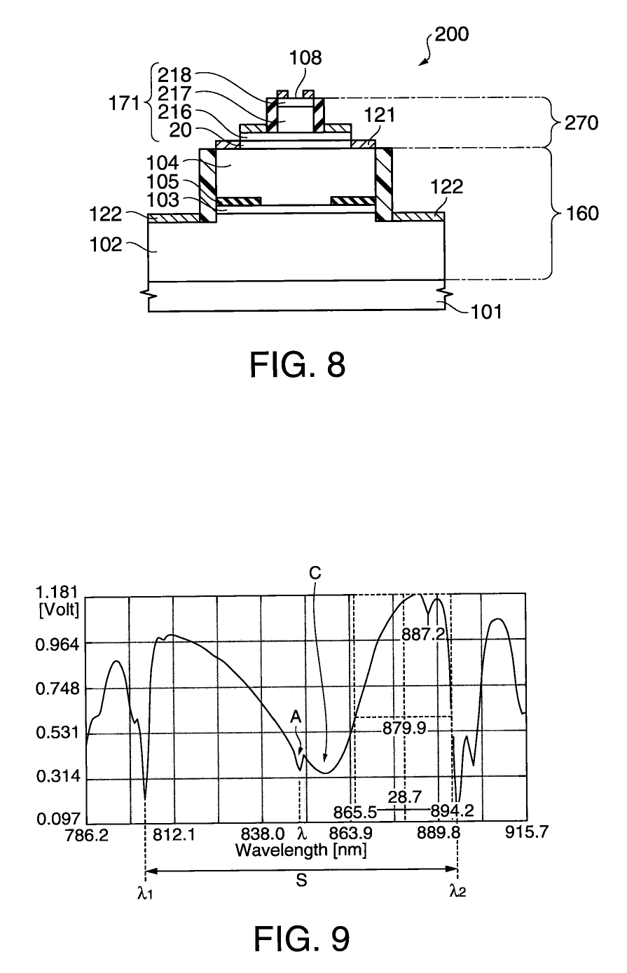

(1) First, a first modified example is described. FIG. 8 is a schematic cross-sectional view of a surface-emitting type semiconductor laser 200 in accordance with the modified example.

In the surface-emitting type semiconductor laser 200 in accordance with the modified example, a light emitting section 160 and a diode section 270 are laminated in this order on a substrate 101. The diode section 270 is a photodetector section, and can function as a photodiode for monitoring.

The diode section 270 may include, as shown in FIG. 8, for example, an isolation section 20 composed of intrinsic semiconductor, a first semiconductor layer 216 of a first conductivity type (for example, p-type) formed on the isolation section 20, and a second semiconductor layer 218 of a second conductivity type (for example, n-type) formed above the first semiconductor layer 216. The diode section 270 may further include a photoabsorption layer 217 composed of intrinsic semiconductor formed between the first semiconductor layer 216 and the second semiconductor layer 218. In the present embodiment example, the semiconductor layer 171 of the example of surface-emitting type semiconductor laser 100 corresponds to the entirety of the isolation section 20, the first semiconductor layer 216, the photoabsorption layer 217 and the second semiconductor layer 218.

In the present modified example, like the example of surface-emitting type semiconductor laser 100, by obtaining a reflection spectrum of the semiconductor multilayer film obtained through forming layers on the substrate 101, whether or not each of the layers is formed to a desired film thickness can be judged.

(2) Next, a second modified example is described.

For example, the substrate 101 in the example of surface-emitting type semiconductor laser 100 may be separated by using, for example, an epitaxial lift off (ELO) method. In other words, the surface-emitting type semiconductor laser 100 may not be provided with the substrate 101.

It is noted that, in the example of surface-emitting type semiconductor laser 100, the light emitting section 160 and the diode section 170 are laminated in this order on the substrate 101. However, the order may be reversed, such that the diode section 170 and the light emitting section 160 may be laminated in this order on the substrate 101. In this case, a reflection coefficient examination on the semiconductor multilayer film 150 described above may be conducted through, after separating the substrate 101 by using an ELO method, irradiating light from the side of the back surface of the semiconductor multilayer film 150 (from the side of the substrate 101 that is separated) and reflecting thereon.

(3) Next, a third modified example is described. FIG. 9 and FIG. 10 are diagrams showing a reflection spectrum of a semiconductor multilayer film 150 in accordance with the present modified example.

In the example of surface-emitting type semiconductor laser 100 described above, the optical film thickness of the semiconductor layer 171 is not an odd multiple of λ/4 or an even multiple of λ/4. In contrast, according to the present modified example, the optical film thickness of the semiconductor layer 171 can be, for example, an odd multiple of λ/4. In this case, for example, a reflection spectrum shown in FIG. 9 can be obtained. In other words, even when the optical film thickness of the semiconductor layer 171 is an odd multiple of λ/4, the position of a dip C caused by photoabsorption of the semiconductor layer 171 in the reflection spectrum can be placed inside the stop band S of the first mirror 102 and the second mirror 104, like the example of surface-emitting type semiconductor laser 100. Furthermore, the minimum section of the dip C caused by photoabsorption of the semiconductor layer 171 can be deviated from the dip A caused by photoabsorption of the active layer 103. Accordingly, even in the reflection spectrum obtained when the optical film thickness of the semiconductor layer 171 is set to an odd multiple of λ/4, the dip A for confirming the design wavelength λ of light that is emitted from the light emitting section 160, and the stop band S of the first mirror 102 and the second mirror 104 can be observed, as shown in FIG. 9.

According to the present modified example, the optical film thickness of the semiconductor layer 171 can be, for example, an even multiple of λ/4. In this case, for example, a reflection spectrum shown in FIG. 10 can be obtained. In other words, even when the optical film thickness of the semiconductor layer 171 is an even multiple of λ/4, the positions of two dips C caused by photoabsorption of the semiconductor layer 171 in the reflection spectrum can be placed inside the stop band S of the first mirror 102 and the second mirror 104, like the example of surface-emitting type semiconductor laser 100. Furthermore, the minimum sections of the dips C caused by photoabsorption of the semiconductor layer 171 can be deviated from the dip A caused by photoabsorption of the active layer 103. For example, the minimum sections of the dips C caused by photoabsorption of the semiconductor layer 171 can be positioned on both sides of the dip A caused by photoabsorption of the active layer 103.

Accordingly, even in the reflection spectrum P obtained when the optical film thickness of the semiconductor layer 171 is an even multiple of λ/4, the dip A for confirming the design wavelength λ of light that is emitted from the light emitting section 160, and the stop band S of the first mirror 102 and the second mirror 104 can be observed, as shown in FIG. 10.

(4) It is noted that the modified examples described above are examples, and the invention is not limited to them. For example, the modified examples may be appropriately combined with one another.

5. Embodiments of the invention are described above in detail. However, a person having an ordinary skill in the art should readily understand that many modifications can be made without departing in substance from the novel matter and effect of the invention. Accordingly, those modified examples are also deemed included in the scope of the invention.

The entire disclosure of Japanese Application Nos: 2006-193075, filed Jul. 13, 2006 and 2007-107336, filed Apr. 16, 2007 are expressly incorporated by reference herein.

What is claimed is:

1. A surface-emitting type semiconductor laser comprising:
a light emitting section having a first mirror, an active layer formed above the first mirror and a second mirror formed above the active layer;
a support section having layers that are common with the first mirror, the active layer and the second mirror; and
a diode section having a semiconductor layer formed above the support section,
an optical film thickness of the semiconductor layer being not an odd multiple or an even multiple of λ/4, where λ is a design wavelength of light that is emitted by the light emitting section.

2. A surface-emitting type semiconductor laser comprising:
a light emitting section having a first mirror, an active layer formed above the first mirror and a second mirror formed above the active layer;
a support section having layers that are common with the first mirror, the active layer and the second mirror; and
a diode section having a semiconductor layer formed above the support section,
a dip caused by photoabsorption of the semiconductor layer in a reflection spectrum being located inside a stop band of the first mirror and the second mirror, and a minimum section of the dip by photoabsorption of the semiconductor layer being deviated from a dip caused by photoabsorption of the active layer.

3. A surface-emitting type semiconductor laser according to claim 1,
the diode section being composed of the semiconductor layer, and the semiconductor layer being formed directly on a layer common with the second mirror of the support section.

4. A surface-emitting type semiconductor laser comprising:
a light emitting section having a first mirror, an active layer formed above the first mirror and a second mirror formed above the active layer; and
a diode section having a semiconductor layer formed above the light emitting section,
an optical film thickness of the semiconductor layer being not an odd multiple or an even multiple of λ/4, where λ is a design wavelength of light that is emitted by the light emitting section.

5. A surface-emitting type semiconductor laser comprising:
a light emitting section having a first mirror, an active layer formed above the first mirror and a second mirror formed above the active layer; and
a diode section having a semiconductor layer formed above the light emitting section,
a dip caused by photoabsorption of the semiconductor layer in a reflection spectrum being located inside a stop band of the first mirror and the second mirror, and a minimum section of the dip by photoabsorption of the semiconductor layer being deviated from a dip caused by photoabsorption of the active layer.

6. A surface-emitting type semiconductor laser according to claim 4,
the diode section being composed of the semiconductor layer, and the semiconductor layer being formed directly on the second mirror.

7. A surface-emitting type semiconductor laser according to claim 1,
the light emitting section and the diode section being electrically connected in parallel with each other, and the diode section having a rectification action in a reverse direction with respect to the light emitting section.

8. A surface-emitting type semiconductor laser according to claim 1,
the diode section being a photodetector section, and the semiconductor layer having a photoabsorption layer.

9. A surface-emitting type semiconductor laser according to claim 1,
the semiconductor layer including a first semiconductor layer of a first conductivity type, and a second semiconductor layer of a second conductivity type formed above the first semiconductor layer.

10. A surface-emitting type semiconductor laser according to claim 1,
an optical film thickness of the semiconductor layer being greater than λ/4 but smaller than λ/2.

11. A surface-emitting type semiconductor laser according to claim 1,
each of the first mirror and the second mirror being composed of a distributed Bragg reflection type mirror, and an optical film thickness of each layer in the distributed Bragg reflection type mirror being an odd multiple of λ/4.

12. A method for manufacturing a surface-emitting type semiconductor laser, the method comprising the steps of:
forming a multilayer film, including the steps of forming a first mirror above a substrate, forming an active layer above the first mirror, forming a second mirror above the active layer, and forming a semiconductor layer above the second mirror;
conducting a reflection coefficient examination on the semiconductor multilayer film, after the step of forming a semiconductor multilayer film; and
patterning the semiconductor multilayer film to form a light emitting section having the first mirror, the active layer and the second mirror, and a diode section having the semiconductor layer, after the step of conducting a reflection coefficient examination,
the semiconductor layer being formed to have an optical film thickness that is not an odd multiple or an even multiple of λ/4, where λ is a design wavelength of light that is emitted by the light emitting section.

13. A method for manufacturing a surface-emitting type semiconductor laser, the method comprising the steps of:
forming a semiconductor multilayer film, including the steps of forming a first mirror above a substrate, forming an active layer above the first mirror, forming a second mirror above the active layer, and forming a semiconductor layer above the second mirror;
conducting a reflection coefficient examination on the semiconductor multilayer film, after the step of forming a semiconductor multilayer film; and
patterning the semiconductor multilayer film to form a light emitting section having the first mirror, the active layer and the second mirror, and a diode section having the semiconductor layer, after the step of conducting a reflection coefficient examination,
a dip caused by photoabsorption of the semiconductor layer in a reflection spectrum obtained by the reflection coefficient examination being inside a stop band of the first mirror and the second mirror, and a minimum section of the dip caused by photoabsorption of the semiconductor layer being deviated from a dip caused by photoabsorption of the active layer.
